(19) United States
(12) Patent Application Publication
(10) Pub. No.: US 2015/0311387 A1
(43) Pub. Date: Oct. 29, 2015

(54) CHIP WITH ENHANCED LIGHT EXTRACTION

(71) Applicant: CREE, INC., Durham, NC (US)

(72) Inventors: Sten Heikman, Goleta, CA (US); Jeffrey Vincent DiMaria, Goleta, CA (US)

(21) Appl. No.: 14/697,282

(22) Filed: Apr. 27, 2015

Related U.S. Application Data
(60) Provisional application No. 61/985,069, filed on Apr. 28, 2014.

(51) Int. Cl. H01L 33/10; H01L 33/22; H01L 33/32; H01L 27/15; H01L 33/58; H01L 33/24; H01L 33/08; H01L 33/00; H01L 33/60

(52) U.S. Cl. CPC H01L 33/10; H01L 33/0075; H01L 33/22; H01L 33/32; H01L 33/60; H01L 33/58; H01L 33/24; H01L 33/08; H01L 27/15; H01L 2933/0058

(57) ABSTRACT

Described herein are devices and methods incorporating light extraction features for improving light extraction in light emitting diode (LED) chips, for example, thin-film semiconductor LED chips such as thin film GaN chips. These features can be located in the semiconductor diode region of an LED chip and are configured to improve device light extraction by redirecting light emitted by the chip's active region. In some embodiments, the light extraction features can comprise a material with a refractive index lower than the surrounding semiconductor material. In some embodiments, the light extraction features are shaped to improve light extraction and can be formed as protrusions, indentations and can comprise various features such as sloped sidewalls. Also disclosed herein are contact configurations for improving electrical conductivity in the disclosed devices.

### CROSS REFERENCE TO RELATED APPLICATIONS

This application claims the benefit of U.S. Provisional Application 61/985,069 to Heikman, filed on Apr. 28, 2014, entitled CHIP WITH ENHANCED LIGHT EXTRACTION, which is hereby incorporated herein in its entirety by reference.

### BACKGROUND

1. Field of the Invention

Described herein are devices and methods relating to light emitting diodes (LED), for example, LEDs comprising a thin-film diode region, which incorporate features for improving light extraction.

2. Description of the Related Art

LED-based light emitting devices are increasingly being used in lighting/illumination applications, with one ultimate goal being a replacement for the ubiquitous incandescent light bulb.

Semiconductor LEDs are widely known solid-state lighting elements that are capable of generating light upon application of voltage thereto. LEDs generally comprise a diode region having first and second opposing faces, and including therein an n-type doped layer, a p-type doped layer and a p-n junction active region. An anode contact ohmically contacts the p-type layer and a cathode contact ohmically contacts the n-type layer. When a bias is applied across the doped layers, holes and electrons are injected into the active region where they recombine to generate light. Light is produced in the active region and emitted from one or more emission surfaces of the LED.

The diode region may be epitaxially formed on a substrate, such as a sapphire, silicon, silicon carbide, gallium arsenide, gallium nitride, etc., growth substrate, but such a substrate can be later removed and the completed device may not include a substrate. The diode region may be fabricated, for example, from silicon carbide, gallium nitride, gallium phosphide, aluminum nitride, indium gallium nitride, aluminum gallium nitride, aluminum indium gallium phosphide and/or gallium arsenide-based materials and/or from organic semiconductor-based materials. The thickness of the diode region can vary depending on LED design, with some thin film LEDs having a thickness on the order of a few microns.

One issue affecting the efficiency of light extraction from an LED device is light becoming trapped and/or absorbed due to total internal reflection (TIR). TIR occurs when a ray of light emitted from the active region strikes a medium boundary, for example, the boundary between an emission surface and the ambient, at an angle larger than a particular critical angle with respect to the normal to the surface. In order to reduce the occurrence of TIE of rays of emitted light at emission surfaces of the LED, and thus improve device light extraction, many contemporary LED devices roughen one or more of these boundaries via mechanical, laser and/or chemical means.

The roughening of the boundaries encourages light extraction based upon a particle model of light emission analysis. Light energy can be described via both particle and wave models and the particle-based model utilizes geometric optics analysis, which sets forth that the roughened surfaces can be effective in scattering impinging photons by altering the angle at which the photon strikes the surface. This increases light extraction by either extracting the photon directly from the surface or redirecting it in a more-or-less random direction inside the semiconductor material. One consequence of this is that photons only escape once the incident angle relative to the localized semiconductor material surface normal is within a certain escape zone. On average, it takes a plurality of redirections for the light to escape.

There are several conventional examples of utilizing the above-discussed roughening principles in LED devices. FIG. 1 shows one such example LED chip 10, comprising an n-type layer 12, a p-type layer 14, an active region 16 therebetween, and a p-contact 18, which can be reflective and serve as a device reflector. As shown in FIG. 1, the top emission surface 20 can be roughened to provide varying surface to redirect light. FIG. 2 shows a similar LED chip 30 also comprising an n-type layer 12, a p-type layer 14 and an active region 16. The LED chip 30 further comprises an n-contact 32, a p-contact 18, a transparent substrate 34, for example, a sapphire substrate, and a transparent conducting oxide (TCO) layer 36. As shown in FIG. 2, portions of the interface 38 between the transparent substrate 34 and the n-layer 12 can be roughened to improve light extraction from the transparent substrate. This device can be fabricated, for example, by roughening the top surface of the transparent substrate 34 prior to growing the semiconductor layers 12, 14 upon it. This results in the final device having an internal roughened surface to redirect light. FIG. 3 shows a third example of an LED chip 50, which also comprises an n-type layer 12, a p-type layer 14, an active region 16, an n-contact 32, a p-contact 18, a transparent substrate 34, and a roughened top emission surface 20. The LED chip 50 further comprises a roughed transparent dielectric layer 52 at the interface between the n-type layer 12 and the transparent substrate 34. This roughened transparent dielectric layer 52 can function as an adhesive that binds the semiconductor layers 12, 14 to the transparent substrate 34 during device fabrication and also redirect light.

However, when the semiconductor material is a thin-film layer, there can be a decrease in the effectiveness of the use of surface roughening alone. For example, when the total semiconductor thickness can be only a few microns, up to about 5-6 um, the size of the features that make up the roughness (i.e. the roughed surface indentions and protrusions) is on the order of a micron or less. For these dimensions, which are on the order of a wavelength of the emitted light, geometric optics are not particularly accurate and to calculate light scattering correctly, a wave optics model should be utilized.

In the article: A. David, “Surface-Roughened Light-Emitting Diodes: An Accurate Model,” Journal of Display Technology, Vol 9, no. 5, May 2013, the author presents a wave optics model of a rough GaN surface in an LED device. For waves (i.e. photons) incident at high angles relative to the normal, the calculated scattering characteristics are very different from what geometric optics predict. Only a very small portion of the light escapes, and the back scattered light is predominantly scattered into high angles similar to what is experienced in specular TIR. Therefore, for high angle light, the semiconductor layers function as a waveguide, causing the light to propagate long distances inside the GaN thin film with low probability of escaping. These long path lengths increase the chance of absorption, either by photons reaching discrete absorbing features, such as bond pads or the die edge, or by absorption in elements present throughout the die such as the reflector, transparent conducting layers (e.g. indium tin oxide (ITO)), or in quantum wells.

### SUMMARY

Embodiments incorporating features of the present invention include devices and methods which comprise structural light extraction features in the diode region of an LED chip. The diode region can comprise the oppositely doped semiconductor layers and the active region therebetween. These light extraction features are configured to break up the typical guided modes of the light, thus minimizing the chance of absorption associated with long path lengths in the diode region, particularly in the case of thin-film LED chips, such as thin film GaN chips. When considering thin-film LED chips, these structural light extraction features introduced within the diode region itself function more efficiently than the typical “roughened interface” features in the conventional art due to the light exhibiting more wave-like properties as discussed above.

These structural light extraction features effectively scatter high angle emitted light, either extracting it directly or directing it away from the guided modes such that it has high probability of being extracted within a small number of redirections at nearby interfaces. Numerous structural features can be placed throughout the lateral extent of the diode region, in a regular or irregular pattern, such that photons on average encounter a structure prior to encountering substantial absorption losses.

In some embodiments incorporating features of the present invention, the light extraction features can comprise protruding or indented shapes and can be formed on surfaces opposite to an emission surface or on the same side as an emission surface. In some embodiments, the light extraction features combine both protruding and indentation embodiments within a single feature. In some embodiments, the light extraction features dissect the active region of the diode region of the LED chip.

In one embodiment, an LED chip comprises a semiconductor material based diode region comprising an active region and one or more light extraction features present at a depth of 40% or greater of the thickness of the diode region. The one or more light extraction features are configured to redirect light emitted from the active region to improve light extraction from an emission surface of the LED chip.

In another embodiment, an LED comprises a semiconductor material based diode region comprising an active region, wherein the diode region further comprises an emission surface. The LED chip further comprises a reflector opposite said emission surface and one or more light extraction features within the diode region between the reflector and the emission surface. The one or more light extraction features comprise a dielectric material protrusion opposite the emission surface.

In a yet another embodiment, an LED chip comprises a semiconductor material based diode region comprising an active region and an emission surface, a reflector opposite the emission surface one or more light extraction features within the diode region between the transparent substrate and the emission surface. Wherein the one or more light extraction features comprises an indentation on the same side of said diode region as said emission surface.

In still another embodiment, an LED chip comprises: a semiconductor material based diode region comprising an active region, an n-type layer and a p-type layer; at least one anode contact contacting the p-type layer; at least one cathode contact contacting the n-type layer and a plurality of light extraction features within the diode region. The plurality of light extraction features are configured to redirect incoming light emitted from the active region to improve light extraction from one or more emission surfaces of the LED chip.

In still a further embodiment, a method of improving light extraction in an LED chip comprises forming a mask layer on an n-type GaN layer of a semiconductor based diode region, which comprises a layer of n-type GaN on a layer of p-type GaN. Next one etches the n-type GaN layer to form one or more indentation light extraction features comprising sloped sidewalls utilizing an etchant that will self-terminate the etching process when the etchant reaches said p-type GaN layer.

These and other further features and advantages of the invention would be apparent to those skilled in the art from the following detailed description, taken together with the accompanying drawings, wherein like numerals designate corresponding parts in the figures, in which:

### BRIEF DESCRIPTION OF THE DRAWINGS

FIG. 1 is front sectional view of a prior art LED chip in contemporary use;

FIG. 2 is front sectional view of a prior art LED chip in contemporary use;

FIG. 3 is front sectional view of a prior art LED chip in contemporary use;

FIG. 4A is front sectional view of an embodiment of an LED chip incorporating features of the present invention;

FIG. 4B is front sectional view of an embodiment of an LED chip incorporating features of the present invention;

FIG. 4C is front sectional view of an embodiment of an LED chip incorporating features of the present invention;

FIG. 5 is front sectional view of an embodiment of a light extraction feature incorporating features of the present invention;

FIG. 6 is front sectional view of an embodiment of a light extraction feature incorporating features of the present invention;

FIG. 7 is front sectional view of an embodiment of a light extraction feature incorporating features of the present invention;

FIG. 8 is front sectional view of an embodiment of a light extraction feature incorporating features of the present invention;

FIG. 9 is front sectional view of an embodiment of a light extraction feature incorporating features of the present invention;

FIG. 10 is front sectional view of an embodiment of a light extraction feature incorporating features of the present invention;

FIG. 11 is front sectional view of an embodiment of a light extraction feature incorporating features of the present invention;

FIG. 12 is front sectional view of an embodiment of a light extraction feature incorporating features of the present invention;

FIG. 13A is front sectional view of an embodiment of a light extraction feature incorporating features of the present invention;

FIG. 13B is front sectional view of an embodiment of a light extraction feature incorporating features of the present invention;

FIG. 14A is a front sectional view showing the positioning of an etching mask in relation to a light extraction feature during an embodiment of a method of manufacture of an LED chip incorporating features of the present invention;

FIG. 14B is a front sectional view showing the positioning of an etching mask in relation to a light extraction feature during an embodiment of a method of manufacture of an LED chip incorporating features of the present invention;

FIG. 14C is a front sectional view showing the positioning of an etching mask in relation to a light extraction feature during an embodiment of a method of manufacture of an LED chip incorporating features of the present invention;

FIG. 14D is a front sectional view showing the positioning of an etching mask in relation to a light extraction feature during an embodiment of a method of manufacture of an LED chip incorporating features of the present invention;

FIG. 15 is front sectional view of an embodiment of an LED chip incorporating features of the present invention;

FIG. 16A is a top view of an embodiment of an LED chip incorporating features of the present invention;

FIG. 16B is a top view of an embodiment of an LED chip incorporating features of the present invention;

FIG. 16C is a top view of an embodiment of an LED chip incorporating features of the present invention;

FIG. 16D is a top view of an embodiment of an LED chip incorporating features of the present invention;

FIG. 17 is a top view of an embodiment of an LED chip incorporating features of the present invention;

FIG. 18A is front sectional view of an embodiment of a light extraction feature incorporating features of the present invention;

FIG. 18B is front sectional view of an embodiment of a light extraction feature incorporating features of the present invention;

FIG. 18C is front sectional view of an embodiment of a light extraction feature incorporating features of the present invention;

FIG. 19A is front sectional view of an embodiment of a light extraction feature incorporating features of the present invention;

FIG. 19B is front sectional view of an embodiment of a light extraction feature incorporating features of the present invention;

FIG. 19C is front sectional view of an embodiment of a light extraction feature incorporating features of the present invention;

FIG. 20A is front sectional view of an embodiment of a light extraction feature incorporating features of the present invention;

FIG. 20B is front sectional view of an embodiment of a light extraction feature incorporating features of the present invention;

FIG. 20C is front sectional view of an embodiment of a light extraction feature incorporating features of the present invention; and

FIG. 21 is a top view of an embodiment of an LED chip incorporating features of the present invention.

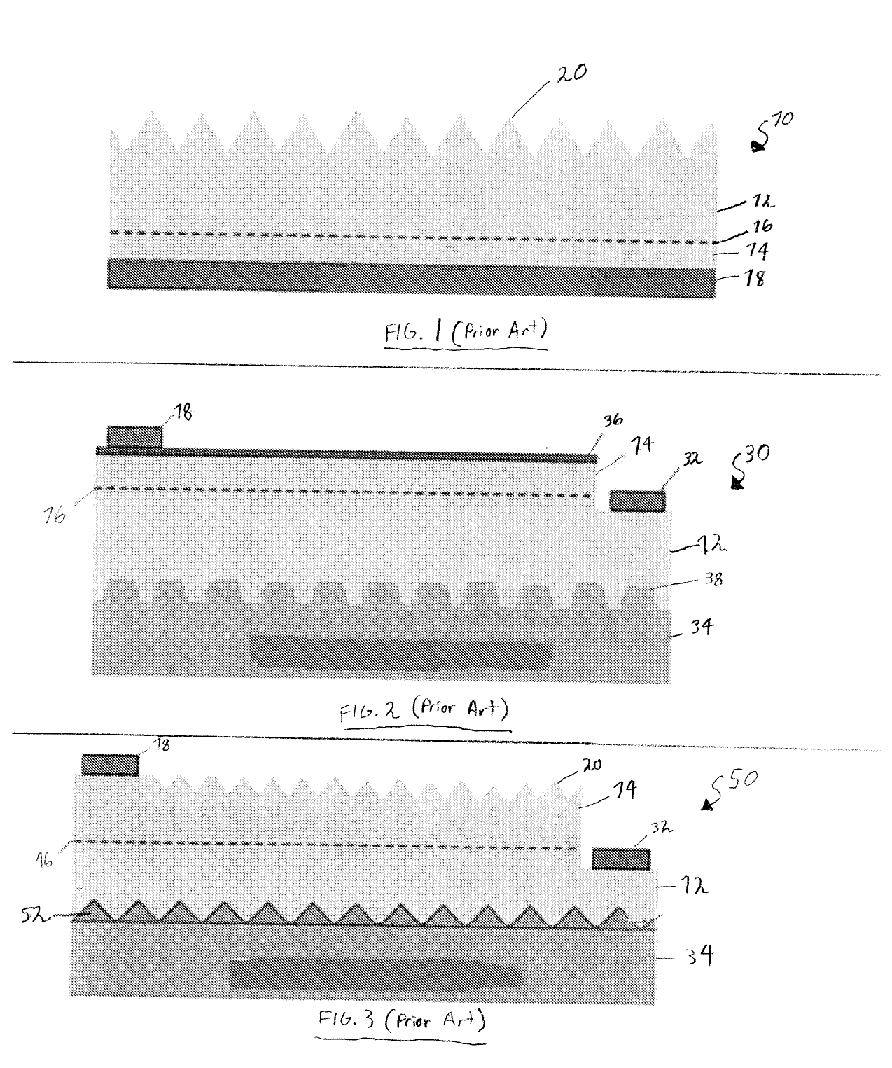

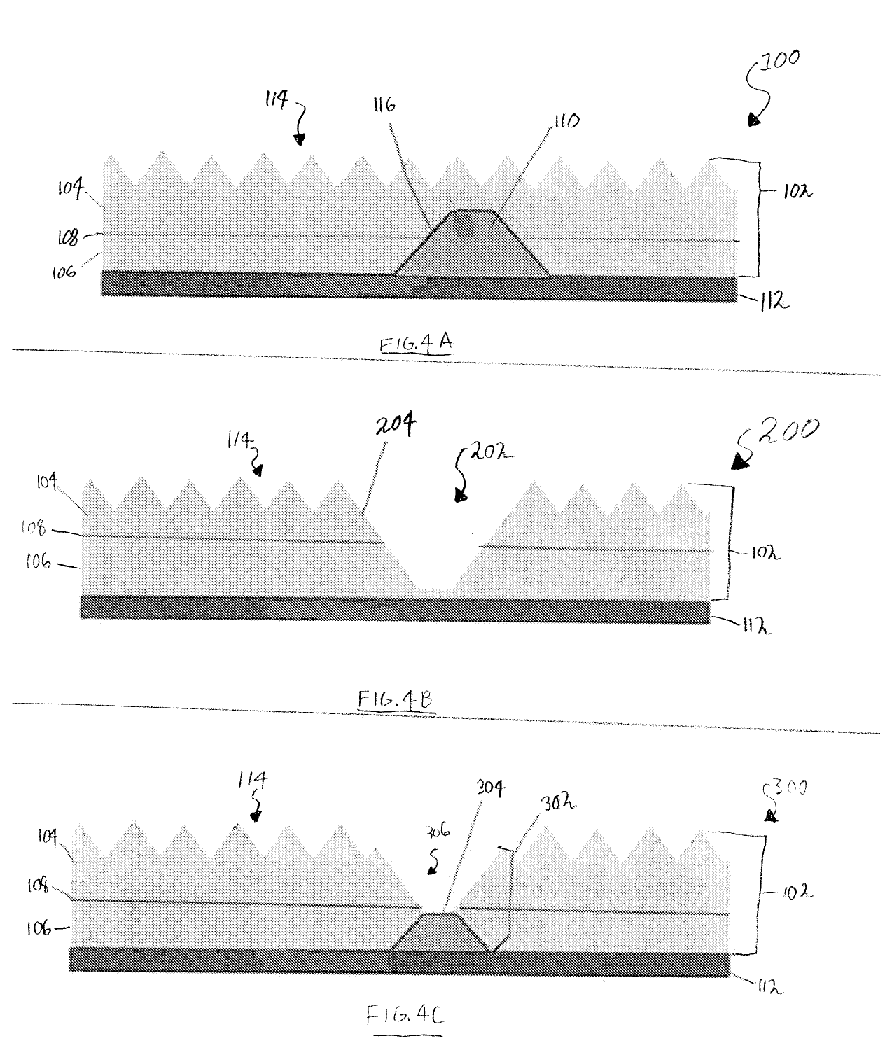

### DETAILED DESCRIPTION

The present disclosure will now set forth detailed descriptions of various embodiments. These embodiments set forth devices and methods pertaining to light emitting devices, such as various LED chips, LED devices, and methods of manufacture thereof. Embodiments incorporating features of the present invention allow for the efficient extraction of light in LED chips and particularly in thin-film LED chips where roughened surfaces alone are particularly ineffective.

Devices and methods incorporating features of the present invention include forming light extraction features within the diode region of an LED chip. While some conventional devices include roughening of an interface, for example, an emission surface, the light extraction features according to the present disclosure are in the diode region itself and can interact with and alter the direction of emitted light that has not yet reached such an interface and would otherwise become trapped within the device and/or absorbed. Such light extraction features are of particular importance in thin-film LED chips, wherein conventional surface roughening alone is insufficient to promote acceptable light extraction. In some embodiments, the light extraction features can dissect the active region of the diode layer, that is, a portion of the light extraction feature can be present in the active region, for example, by occupying space in both oppositely doped semiconductor layers of the diode region and the active layer therebetween.

The light extraction features can be present in the diode region to a variety of depths of the diode region thickness as needed to enhance light extraction. In some embodiments, the light extraction features can be present in the diode region to a depth of 40% of the diode region or greater. In other embodiments, the light extraction features can be present in the diode region to a depth of 50% of the diode region or greater; for thin film LEDs having a diode region of approximately 4 microns thick, this would include extraction features having a height of 2 microns or greater. In still other embodiments, the light extraction features can be present in the diode region to a depth of 60% of the diode region or greater. In yet other embodiments, the light extraction features can be present in the diode region to a depth of 100% of the diode region.

It is understood that devices according to the present invention can include diode regions comprising one or more of the following: functional or non-functional layers, for example, doped layers, undopped layers, n-type layers, p-type layers, barrier layers, spreading layers and/or capping layers. In one embodiment, the multiple quantum wells of the diode region can be capped by an undoped layer, for example, an undoped layer that is intrinsically n-type. Further examples of such multiple-layer diode regions can be found in U.S. Pat. No. 8,044,384 to Bergmann, et al., entitled Group III Nitride Based Quantum Well Light Emitting Device Structures With an Indium Containing Capping Structure, filed on Feb. 2, 2010, which is hereby incorporated herein in its entirety by reference, including the drawings, charts, schematics, diagrams and related written description.

The light extraction features can be configured in various ways to redirect light emitted from the active region and to otherwise improve light extraction of an LED chip. For example, the light extraction features can comprise a material that facilitates redirection of emitted light to prevent trapping and to help the light escape from the diode region of the LED chip. One such example of this configuration is utilizing a light extraction feature that comprises a material having a lower refractive index than the surrounding medium, that is, the surrounding semiconductor material that the diode region comprises. This increases the instances of TIR at sufficiently high angles, altering the direction of light emitted from the active region and increasing the likelihood that such light will escape from a device emission surface immediately or after a few more redirections.

In some embodiments, the refractive index of the light extraction features is substantially lower than the refractive index of the surrounding diode area. For example, in some embodiments, the light extraction features can comprise a dielectric material such as SiO₂ (n=−1.54), silicone (n=−1.38-1.58), or ambient air (n=−1.0), whereas the surrounding n-type and p-type layers can comprise GaN (n=−2.4). This results in a substantial difference in the index of refraction of about 0.80 to about 1.4.

In one embodiment, the shape and size of the light extraction features can affect the properties of the light extraction. The light extraction features can comprise a variety of different shapes and be angled to alter the direction of incoming light and to improve device light extraction. For example, the light extraction features can comprise forward-sloped or inverted-sloped sidewalls. In other embodiments, the light extraction features can comprise a protruding trapezoidal shape. In some embodiments, the light extraction features can comprise an indentation comprising a portion of the semiconductor diode layer that has been removed, thus creating a sloped shape as well as a light extraction feature comprising a different material than the semiconductor, for example, ambient air. In still other embodiments, the light extraction features can have sidewalls with a slope range of about 20-70 degrees. In some embodiments, the sidewalls have a slope of about 45 degrees.

In some embodiments, the light extraction features can be configured to combine aspects of both the protruding and indented features to enhance light extraction while also preserving effective active region area. This will be discussed in more detail below. Yet other configuration of the light extraction features include mixing and matching the various configurations, for example, different refractive indices, materials, shapes and arrangements in different patterns across a plurality of light extraction features such that the interactions of the light extraction features with each other facilitate device light extraction. Also a single light extraction feature can comprise multiple configurations to further facilitate device light extraction, for example, a single light extraction feature can both comprise a dielectric material with a low index of refraction and also comprise a shape having sloped sidewalls.

Throughout this description, the preferred embodiment and examples illustrated should be considered as exemplars, rather than as limitations on the present invention. As used herein, the term “invention,” “device,” “method,” “present invention,” “present device” or “present method” refers to any one of the embodiments of the invention described herein, and any equivalents. Furthermore, reference to various feature(s) of the “invention,” “device,” “method,” “present invention,” “present device” or “present method” throughout this document does not mean that all claimed embodiments or methods must include the referenced feature(s).

It is also understood that when an element or feature is referred to as being “on” or “adjacent” to another element or feature, it can be directly on or adjacent the other element or feature or intervening elements or features may also be present. It is also understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “outer”, “above”, “lower”, “below”, “horizontal,” “vertical” and similar terms, may be used herein to describe a relationship of one feature to another. It is understood that these terms are intended to encompass different orientations in addition to the orientation depicted in the figures.

It is understood that when a first element is referred to as being “between,” “sandwiched,” or “sandwiched between,” two or more other elements, the first element can be directly between the two or more other elements or intervening elements also be present between the two or more other elements. For example, if a first layer is “between” or “sandwiched between” a second and third layer, the first layer can be directly between the second and third layers with no intervening elements or the first layer can be adjacent to one or more additional layers with the first layer and these additional layers all between the second and third layers.

Although the terms first, second, etc. may be used herein to describe various elements or components, these elements or components should not be limited by these terms. These terms are only used to distinguish one element or component from another element or component. Thus, a first element or component discussed below could be termed a second element or component without departing from the teachings of the present invention. As used herein, the term “and/or” includes any and all combinations of one or more of the associated list items.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” when used herein, specify the presence of stated features, integers, steps, operations, elements, and/or components, but do not preclude the presence or addition of one or more other features, integers, steps, operations, elements, components, and/or groups thereof.

It is noted that the terms “layer” and “layers” are used interchangeably throughout the application. A person of ordinary skill in the art will understand that a single “layer” of material may actually comprise several individual layers of material. Likewise, several “layers” of material may be considered functionally as a single layer. In other words the term “layer” does not denote an homogenous layer of material. A single “layer” may contain various material concentrations and compositions that are localized in sub-layers. These sub-layers may be formed in a single formation step or in multiple steps. Unless specifically stated otherwise, it is not intended to limit the scope of the invention as embodied in the claims by describing an element as comprising a “layer” or “layers” of material.

While the light extraction features disclosed herein can be utilized to improve light extraction from any LED chip or device, these features are of particular use in thin film semiconductor LED chips and devices as discussed above. As such, when the present disclosure refers to an embodiment utilizing a thin-film semiconductor layer, it is understood that the same embodiment can be used in another LED device having a thicker semiconductor diode layer.

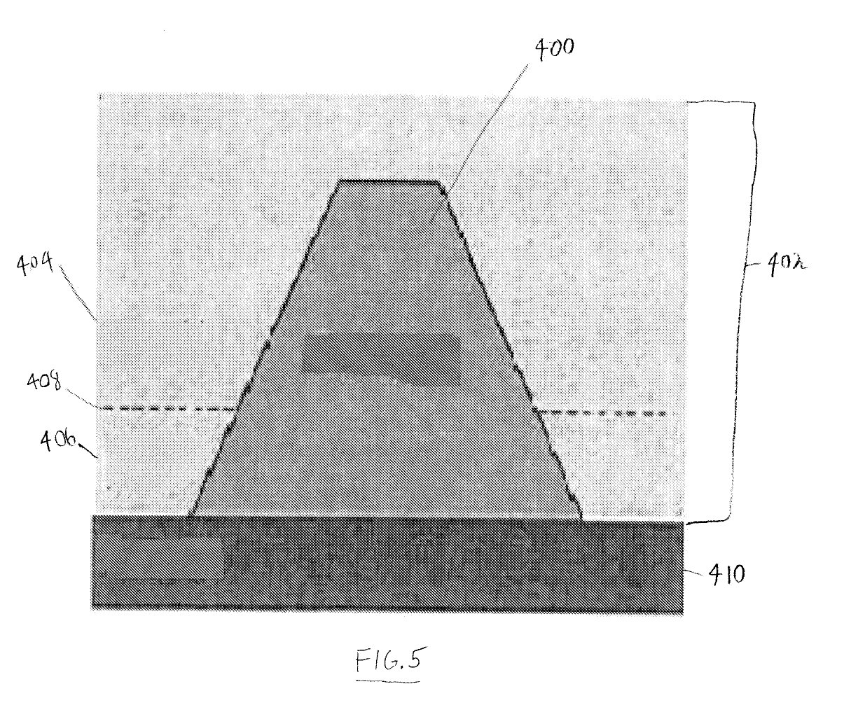

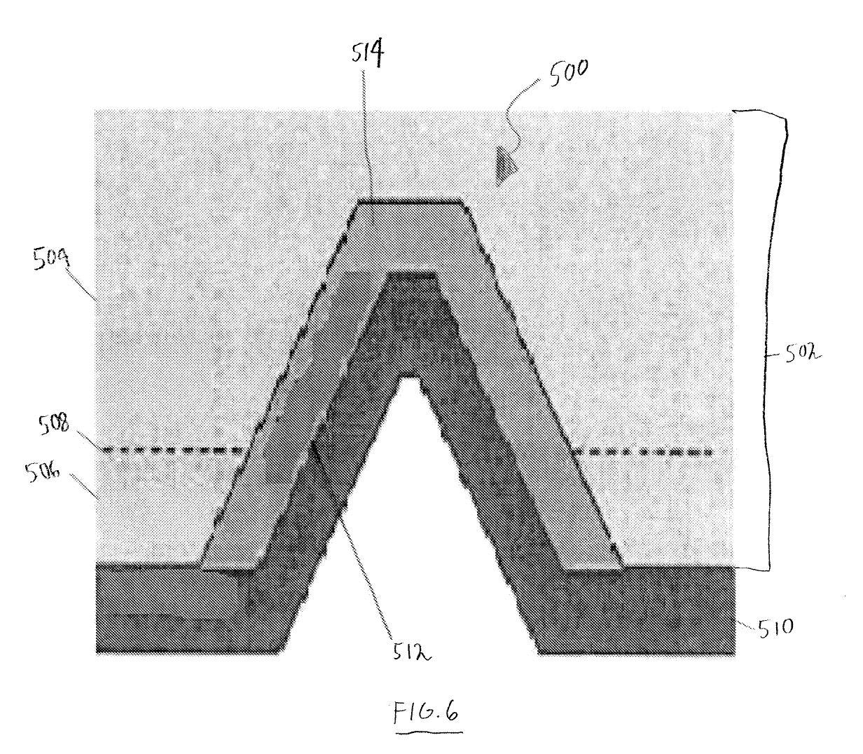

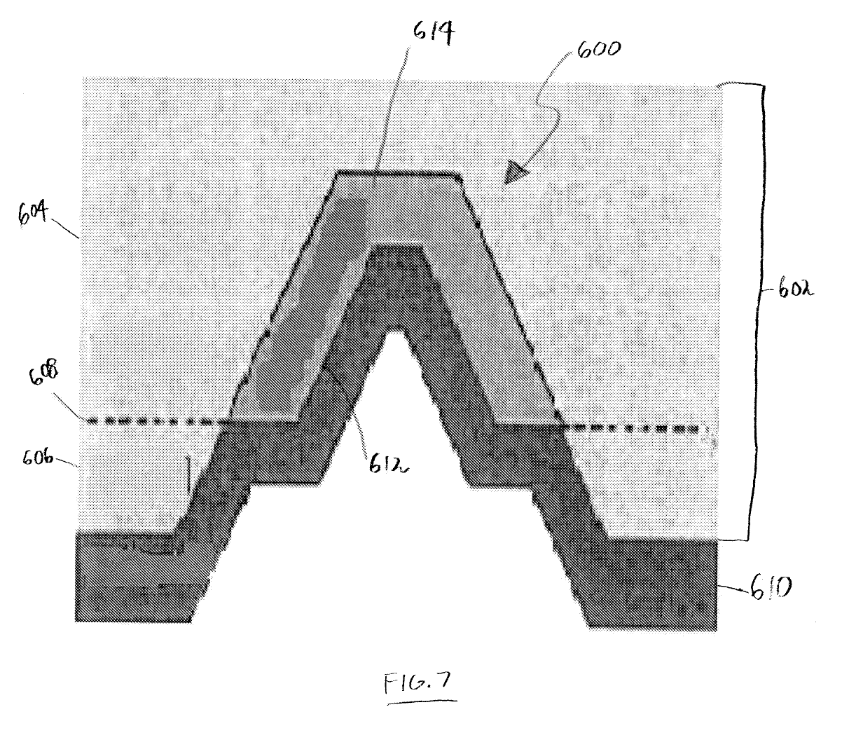

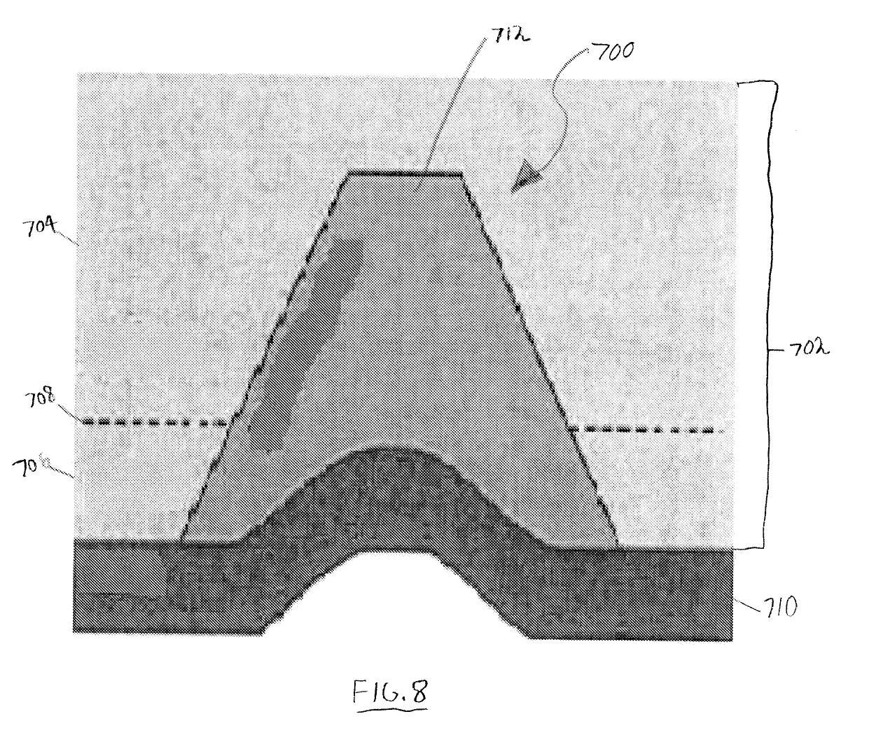

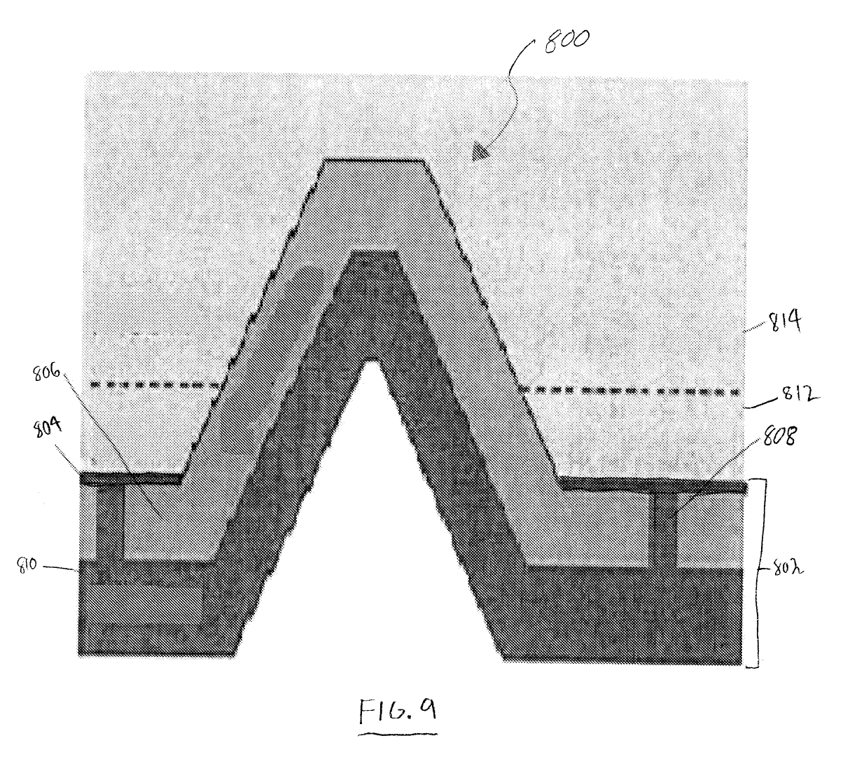

Three embodiments of light extraction feature configurations incorporating features of the present invention are shown in FIGS. 4A-4C. These configurations can be utilized with any LED chip, including a thin film LED chip. Some embodiments can comprise a GaN based LED chip with a semiconductor diode region approximately 3-4 microns thick. FIG. 4A shows one embodiment of an LED chip 100 comprising a semiconductor-based diode region 102, which comprises an n-type doped semiconductor layer 104, a p-typed doped semiconductor layer 106 and an active region 108 in between the two oppositely doped semiconductor layers 104, 106. While embodiments shown herein will disclose an n-type layer positioned on a p-type layer, it is understood that in some embodiments incorporating features of the present invention, these layers are inverted such that the p-type layer is on the n-type layer.

The LED chip 100 further comprises one or more light extraction features 110 (one shown) and can optionally comprise one or more reflectors 112 (one shown), which can also be the p-contact of the LED chip 100. In the embodiment shown in FIG. 4A, there is a top emission surface 114 opposite the reflector 110, although it is understood that in some embodiments, there can be multiple emission surfaces, for example bottom and/or side emission surfaces. In the embodiment shown, the top emission surface 114 is optionally roughened, although in other embodiments, multiple surfaces can be roughened or no surfaces at all can be roughened. As shown in FIG. 4A, the light extraction feature 110 can dissect the active region 108.

The basic structure of light emitting diodes is generally known in the art and is therefore only briefly discussed herein. The diode region 102 can comprise two oppositely doped semiconductor layers 104, 106 with an active region therebetween. An anode contact (e.g. reflector) ohmically contacts the p-type doped layer 106 and a cathode contact ohmically contacts the n-type doped layer 104. When a bias is applied across the doped layers, holes and electrons are injected into the active region where they recombine to generate light. One suitable semiconductor material to utilize for the diode region is GaN, although any semiconductor material known in the art for use in the manufacture of LEDs are within the scope of this disclosure. Some example semiconductor materials include, but not limited to, materials comprising: Gallium arsenide (GaAs), Aluminium gallium arsenide (AlGaAs), Gallium arsenide phosphide (GaAsP), Aluminium gallium indium phosphide (AlGaInP), Gallium(III) phosphide (GaP), Gallium arsenide phosphide (GaAsP), Aluminium gallium phosphide (AlGaP), Indium gallium nitride (InGaN), Aluminium nitride (AlN), Aluminium gallium nitride (AlGaN), Aluminium gallium indium nitride (AlGaInN), and combinations thereof.

Many different LEDs can be used with embodiments incorporating features of the present invention, such as those commercially available from Cree Inc., under its DA, EZ, GaN, MB, RT, TR, UT and XT families of LED chips. The thin-film devices within the DA family of chips particularly benefit from these embodiments. These types of chips are generally described in U.S. patent application Ser. No. 12/463,709 to Donofrio et al., entitled “Semiconductor Light Emitting Diodes Having Reflective Structures and Methods of Fabricating Same,” now issued as U.S. Pat. No. 8,368,100, which is incorporated herein in its entirety by reference, including the drawings, schematics, diagrams and related written description.

The reflector 112 can be any reflective material known in the art for use with light emitting devices, including but not limited to silver, diffuse reflectors such as materials comprising a reflective white color, and thin film reflectors, such as metals or dielectric layers. The reflector can also be made of various materials known in the art for use as contacts that also happen to be reflective, for example, various metals. These types of dielectric mirror are described in detail in U.S. patent application Ser. No. 13/909,927 to Sten Heikman, et al., entitled LIGHT EMITTING DIODE DIELECTRIC MIRROR, filed on Jun. 4, 2013, which is incorporated herein in its entirety by reference.

The light extraction feature can comprise a material that facilitates the directing, scattering, focusing, and/or otherwise altering the direction and/or nature of, light emitted from the active region 108. For example, the light extraction feature 110 can comprise a material with reflective or lens-like properties (e.g. focusing or changing the direction of incoming light). The light extraction feature 110 can comprise a material different than the material of the diode region 102. The light extraction feature 110 can comprise any dielectric material, for example, SiO₂, silicone, or air. In some embodiments, the light extraction feature 110 can comprise a material having a lower index of refraction than the material of the surrounding diode region 102, this can cause TIR for light incident at sufficiently high angles, resulting in the direction of the light being altered.

In addition to or in lieu of configuring the light extraction feature 110 based upon material selection or alteration, the light extraction feature 110 can be configured to improve light extraction by configuring its shape. For example, the light extraction feature 110 can comprise sloped sidewalls 116 that can be configured to direct light in a desired direction, for example, toward the emission surface 114. The forward-sloped sidewalls 116 shown in FIG. 4A tend to redirect incoming guided light emitted by the active region 108 in an upward direction, increasing the likelihood that a particular ray of light will escape the LED chip 100.

The light extraction feature 110 is referred to as a “protrusion” or “protrusion feature,” that is, a light extraction feature that comprises a material that has been added and protrudes into to the diode region 102, for example, a dielectric material light extraction feature that has been added to a GaN-based diode region 102. This is in contrast to the “indentation” or “indentation feature” added in FIG. 4B below. An indentation is not a new material feature being added to the semiconductor-based diode region, but is instead an omitted or removed portion of the diode region 102 itself, for example, creating a sloped interface with ambient air via removal of a portion of the diode region. An indentation feature can also be filled with transparent materials such as silicone or epoxy later in the LED fabrication process or during chip packaging.

In some embodiments, the indentation features can be filled with a dielectric materials such as those utilized for protrusion features, such that the “filled” indention features can function as a protrusion feature. It is understood that while the present disclosure typically shows protrusion-features located opposite an emission surface and indentation features located on the same side as an emission surface, it is understood that the opposite can be true. The protrusion and indentation features can be in various locations within the diode region 102 in order to conform to a desired design to facilitate light extraction or to otherwise alter the direction of light emitted by the diode region 108.

Expanding on the above, FIG. 4B shows an LED chip 200, similar to the LED chip 100 in FIG. 4A above, wherein like reference numbers denote like features. The LED chip 200 in FIG. 4B comprises a diode region 102, which comprises an n-type doped semiconductor layer 104, a p-typed doped semiconductor layer 106 and an active region 108 in between the two oppositely doped semiconductor layers 104, 106. Like the LED chip 100 in FIG. 4A above, the LED chip 200 in FIG. 4B can comprise an emission surface 114 and can optionally comprise a reflector 112. The LED chip 200 further comprises an indentation light extraction feature 202, which can comprise sidewalls 204.

In the embodiment shown, the sidewalls 204 are inverted-sloped and thus tend to direct guided light emitted from the active region 108 in a downward direction toward the reflector 112. The indentation light extraction feature 202 can be configured to create a dielectric interface between the semiconductor material of the diode region 102 and the ambient air that is within the inverted light extraction feature 202. The indention light extraction feature 202 can also be filled with a different material, for example, a dielectric material, making the light extraction feature 202 similar to a protrusion light extraction feature.

Light extraction features according to the present disclosure can be inserted into the semiconductor diode region during device fabrication and/or during the formation of the diode region, using any method known in the art, for example, utilizing various doping and implantation processes. Inverted light extraction features can be etched into the diode region using any means known in the art, for example, machining, grinding, embossing as well as chemical, laser and reactive ion etching. Further methods of fabricating LED chips incorporating features of the present invention are discussed further below.

The light extraction features according to the present disclosure can also comprise features combining both protrusion and indentation features. For example, FIG. 4C shows an LED chip 300, similar to the LED chips 100, 200 in FIGS. 4A-4B above, wherein like reference numbers are used to denote like features. The LED chip 300 in FIG. 4C comprises a diode region 102, which comprises an n-type doped semiconductor layer 104, a p-typed doped semiconductor layer 106 and an active region 108 in between the two oppositely doped semiconductor layers 104, 106. Like the LED chips 100, 200 in FIGS. 4A-4B above, the LED chip 300 in FIG. 4C can comprise an emission surface 114 and can optionally comprise a reflector 112. The LED chip 300 further comprises a combined light extraction feature 302 which comprises both a protrusion portion 304 and an indentation portion 306. This configuration enables the LED device 300 to utilize advantages of both protrusion and indentation light extraction features, for example simultaneously utilizing SiO₂ and air as dielectric materials and/or utilizing both forward- and inverted-sloped sidewalls.

Another advantage of the combined light extraction feature 302 shown in FIG. 4C is that such features can utilize the benefits of extraction feature opposite an emission surface while minimizing active area loss. For example, in thin-film devices utilizing a reflector opposite an emission surface, the light emitting quantum wells inside the diode region are typically located close to the reflector side. As a consequence, reflector-side extraction features inherently remove active area from the LED, which results in lower internal quantum efficiency (IQE) due to current density induced efficiency drop. The deeper the feature is, the more area is lost due to the sloped sidewalls. Therefore, an efficiency trade-off exists between light extraction enhancement and the reduction in efficiency, which can affect the optimal spatial frequency of the extraction features.

The combined extraction light feature is a way to compensate for the above-mentioned active area loss while maintaining the good extraction efficiency of the reflector-side extraction feature. Since the reflector-side of the feature can take up less space of the diode region, it can also have reduced lateral size, which leads to less loss of active area. For example, with continued reference to FIG. 4C, the protrusion portion 304 of the combined light extraction feature 302 corresponds to a “reflector side” light extraction feature. The protrusion portion 304 can be configured along with the indentation portion 306 and be made to take up a significantly reduced lateral portion of the diode region when compared to the indention light extraction feature 110 in FIG. 4A above. This preserves lateral active area while also benefiting from the enhanced light extraction imparted by a reflector-side light extraction feature.

Extraction features according to the present disclosure can comprise any shape, for example, any regular or irregular polygon, including shapes that can facilitate enhanced light extraction, including shapes comprising sloped sidewalls as discussed above. FIGS. 5-12 set forth several example shapes extraction features according to the present disclosure can comprise. FIG. 5 shows a light extraction feature 400, within the diode region 402 of an LED chip. The diode region 402 comprises an n-type doped semiconductor layer 404, a p-typed doped semiconductor layer 406 and an active region 408 in between the two oppositely doped semiconductor layers 404, 406. The embodiment shown also comprises a reflector 410. Since the light extraction feature 400 can dissect the active region 408 of the diode region 402, it is important that the metal reflector 410, which serves as the p-contact in the embodiment shown, is not in contact with the n-type layer 404. To prevent this, an isolating dielectric material should be in contact with the n-type layer to prevent electrical shorting which can be caused by the p-type contact electrically contacting the n-type layer. Thus, the light extraction feature 400 in FIG. 5 can comprises a dielectric material.

Other light extraction figure configurations that isolate the reflector from the n-type layer are also possible. For example, FIG. 6 shows a light extraction feature 500, within the diode region 502 of an LED chip. The diode region 502 comprises an n-type doped semiconductor layer 504, a p-typed doped semiconductor layer 506 and an active region 508 in between the two oppositely doped semiconductor layers 504, 506. The embodiment shown also comprises a reflector 510. In the embodiment shown, the reflector 510 contributes to the shape and composition of the light extraction feature 500 and the entire sloped side portion 512 of the reflector 510 is coated with a dielectric material 514 to prevent electrical contact between the reflector 510 and the re-type layer 504 as well as to provide a dielectric interface.

Rather than the entire portion of the sidewalls being covered by a dielectric layer, only a targeted portion can be coated instead. For example, FIG. 7 shows a light extraction feature 600, within the diode region 602 of an LED chip. The diode region 602 comprises an n-type doped semiconductor layer 604, a p-typed doped semiconductor layer 606 and an active region 608 in between the two oppositely doped semiconductor layers 604, 606. The embodiment shown also comprises a reflector 610. In the embodiment shown, like the embodiment in FIG. 6 above, the reflector 510 contributes to the shape and composition of the light extraction feature 600. However, in this embodiment, only the portions of the sloped side portions 612 of the reflector 610 that would otherwise be in contact with the n-type layer 604 are coated with a dielectric material 614. This prevents electrical contact between the reflector 610 and the n-type layer 604.

Various other designs are possible utilizing reflectors with different portions coated by dielectric layers to change the ways in which the light extraction features interact with incoming light. FIG. 8 shows a light extraction feature 700, within the diode region 702 of an LED chip. The diode region 702 comprises an n-type doped semiconductor layer 704, a p-typed doped semiconductor layer 706 and an active region 708 in between the two oppositely doped semiconductor layers 704, 706. The embodiment shown also comprises a reflector 710. In FIG. 8, the dielectric material 712 is coating the sides of the reflector 710, but has a variable thickness. One method by which this type of shape could be produced is by removing semiconductor material from the reflector side and coating the dielectric material with a spin coating process, for example spin-on glass.

Embodiments incorporating features of the present invention can also incorporate various dielectric mirror embodiments. FIGS. 9 and 10 show embodiments of a light extraction feature 800 and 850 respectively, wherein the reflector comprises a “dielectric mirror.” As shown in FIG. 9, the reflector 802 comprises a dielectric mirror, which comprises a transparent conducting oxide (TCO) 804, a dielectric layer 806 with periodic holes 808, and a metal reflector 810. The holes 808 allow the metal reflector 810 to electrically contact the p-type layer 812 of the LED chip through the TCO 804, while the dielectric layer 806 isolates the n-type layer 814 from the metal reflector 810.

The light extraction feature 850 in FIG. 10 is similar to the light extraction feature 800 in FIG. 9 in that it comprises a dielectric mirror reflector 852 which comprises a transparent conducting oxide (TCO) 854, a dielectric layer 856 with periodic holes 858, and a metal reflector 860. The holes 858 allow the metal reflector 860 to electrically contact the p-type layer 862 of the LED chip through the TCO 854, while the dielectric layer 856 isolates the n-type layer 864 from the metal reflector 860. The light extraction feature 850 of FIG. 10 differs from the light extraction feature 800 of FIG. 9 in that has a dielectric material layer 856 having a variable thickness, much like the embodiment shown in FIG. 8.

Many other light extraction feature shapes are also possible. FIG. 11 shows a rectangular light extraction feature 900 within the diode region 902 of an LED chip 904. The LED chip 904 in FIG. 11 further comprises a reflector 906. While such a rectangular shape does not comprise the advantageous sidewalls set forth in many previously described embodiments, it is possible to utilize such a rectangular light extraction feature 900, especially when utilizing it on a smaller size scale as will be discussed further below. This is because some emitted light can interact with an angled side 908 of the light extraction feature rather than simply the straight-walled portions. FIG. 12 shows a light extraction feature 950 within the diode region 952 of an LED chip 954. The LED chip 954 in FIG. 12 further comprises a reflector 956. The light extraction feature 950 comprises both a forward sloped sidewall portion 958 and an inverted sloped sidewall portion 960, utilizing the benefits of both. Furthermore, this sidewall arrangement results in a decreased lateral profile allowing for an increase in effective active area as discussed above.

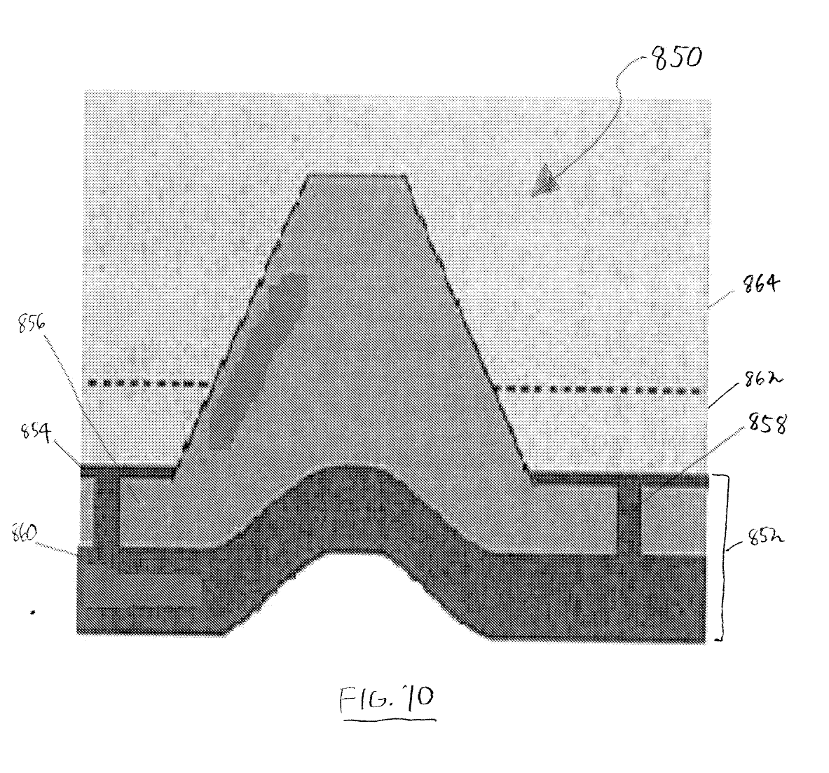

Size is another feature that can configured in light extraction features according to the present disclosure. FIGS. 13A and 13B show a smaller light extraction feature 1000 and a larger light extraction feature 1050 respectively. The smaller light extraction feature 1000 can be near the order of magnitude of two times the wavelength of the light emitted by the device active region. For example, in an LED chip emitting blue light roughly in the range of 450 nanometers, which is roughly 190 nm inside the GaN crystal (450 nm/GaN refractive index), a smaller light extraction feature 1000 can be a size of about 0.38 microns or less (i.e. [190 nm*2=380 nm]). In thin-film GaN LED chips, which typically have a diode region 1002 thickness of about 3-4 microns, there is a portion 1004 of the diode region 1002 not dissected by such a smaller light extraction feature 1000, allowing free flow of current. The larger light extraction feature 1050 of FIG. 13B, however, can dissect the entire active region 1052 and thus hinder electric flow. Configurations for addressing this problem are presented further below. Typically, in a thin film device with a diode region of approximately 3-4 microns in thickness a larger light extraction feature would have a size of about 20 times the wavelength of emitted light inside the GaN crystal and would thus function similar to a regularly reflector layer.

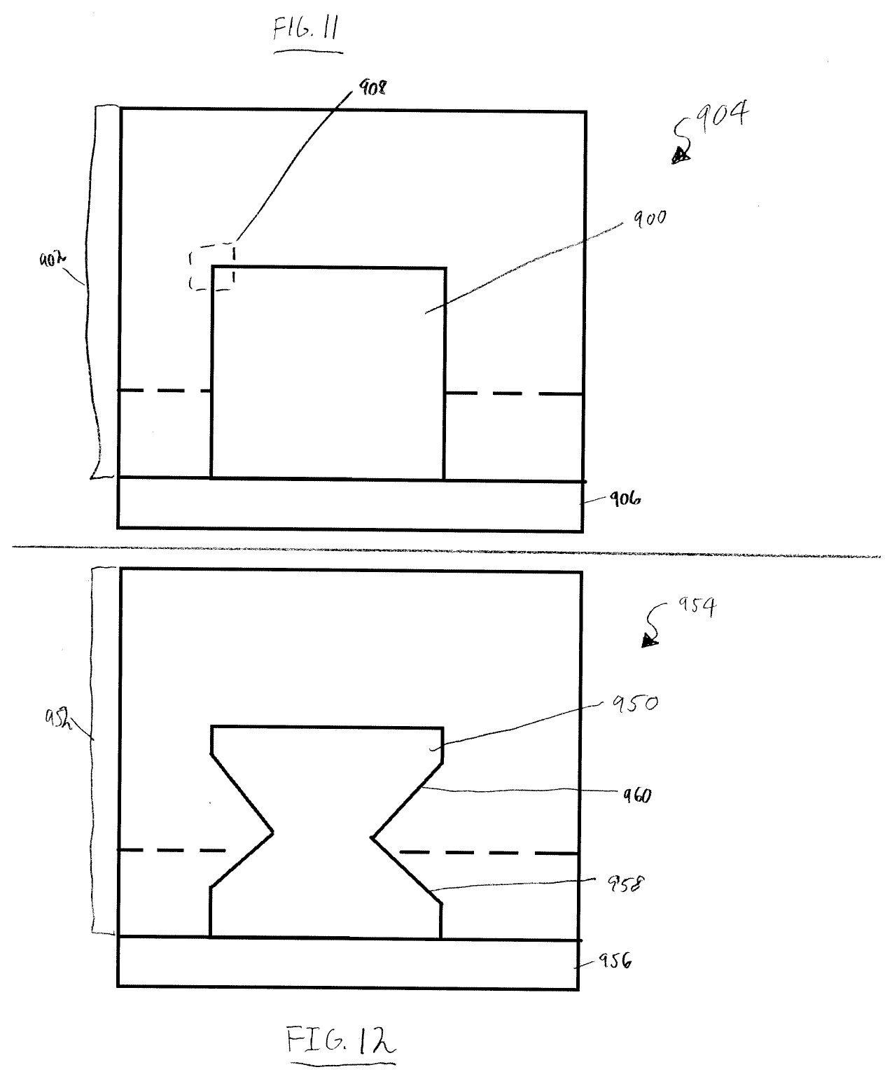

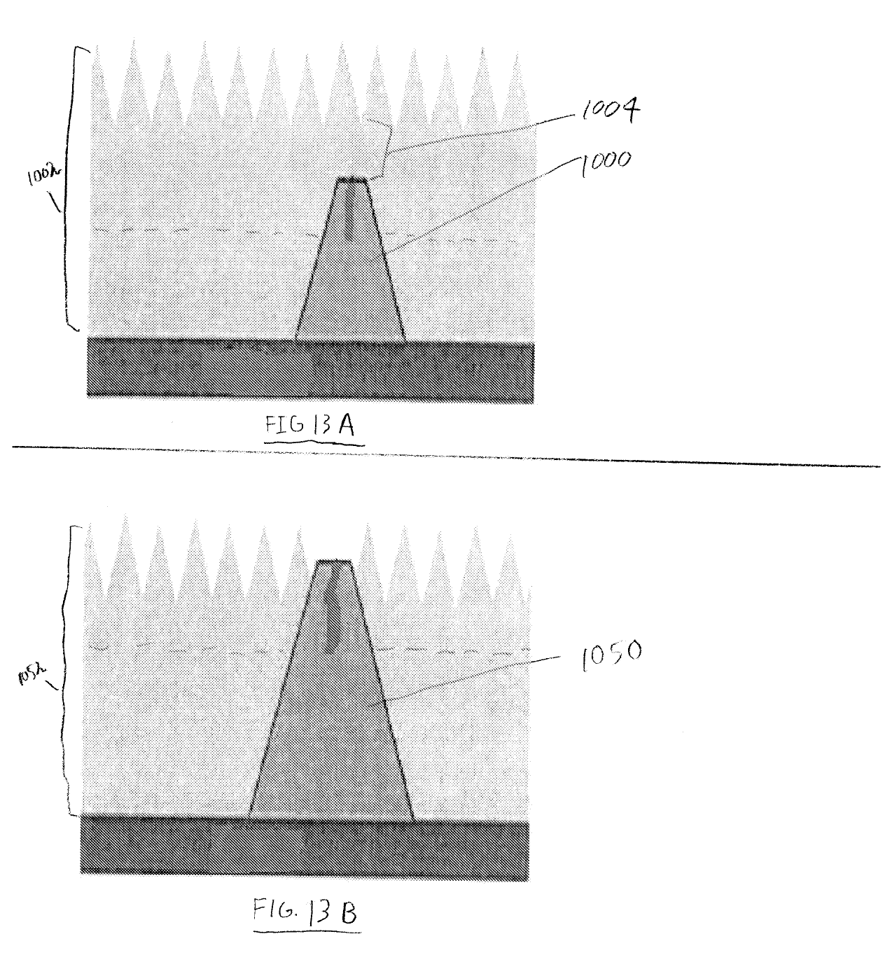

FIG. 14A through 14D show embodiments of devices created by a masked etch. Any etching process that is known in the art can be utilized. For GaN-based devices with the n-type face exposed to certain etchants (including KOH), the etch reveals sloped slide walls with well-defined angles due to the crystalline structure of the material. These sloped side walls are very slow etching causing the etch to effectively self-terminate once all other surfaces have been etched away. Thus, the opening between masked areas can be used to define the etch depth, if the etch is allowed to run long enough to self-terminate. For some etch chemistries the etch also terminates once it reaches p-type GaN or the quantum well region, creating etched wells with sloped side walls and substantially flat bottom surfaces. In FIG. 14A an etch mask 1100 is aligned with a reflector side indention extraction feature 1102, ensuring the extraction feature does not get exposed during the masked etch. In the embodiment of FIG. 14A, the etch is not self-terminated but must be timed. Exposing the extraction feature 1102 may result in reliability problems, since the dielectric portion of the extraction feature may be porous and can let through moisture and other elements to the reflector, which in turn may degrade optically and/or electrically.

FIGS. 14B through 14D show embodiments utilizing self-terminated etches. The etch masks 1150 are spaced such that the etch results in deep features extending through the majority of the diode region 1152 thickness. In FIG. 14B, the reflector-side protrusion extraction feature 1154 is aligned with one of the deep etched features 1156, together forming a combined extraction feature 1158 as previously discussed above. Alternatively the reflector side protrusion extraction feature 1170 can be aligned with the etch mask 1150, as illustrated in FIG. 14C, which ensures that the extraction feature does not get exposed during the masked etch. FIG. 14D shows a variation on FIG. 14B comprising the same combined extraction feature 1158, but where the etch masks 1150 are spaced closer together away from the extraction feature to limit the etch depth.

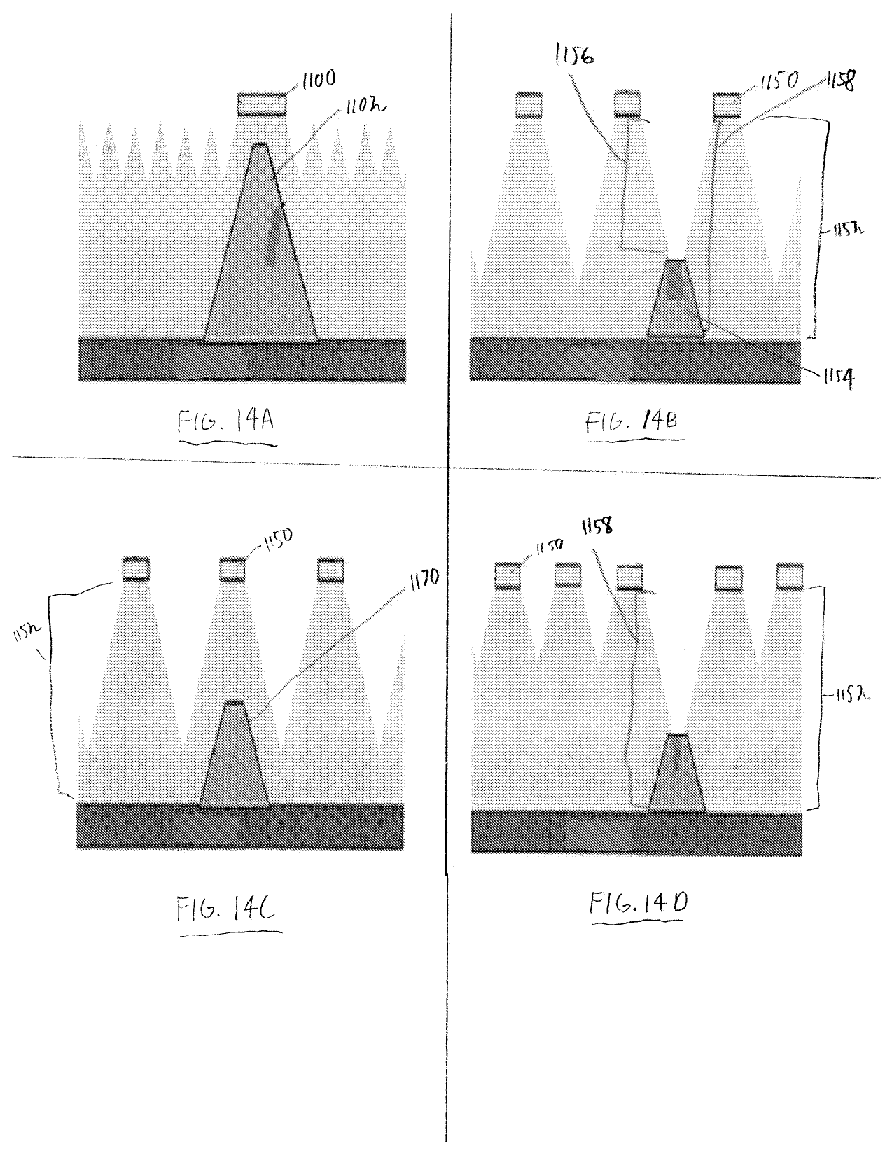

In many of the embodiments set forth above, the light extraction features can dissect a majority of the diode region thickness, and in some cases cut through it completely. In designing LED devices, this has implications on the lateral layout of the light extraction features relative to n- and p-type contacts locations. The light extraction features should not interfere with the current spreading in the n- or p-type semiconductor layers. An example contact arrangement addressing this issue is illustrated in FIG. 15, which is can be viewed as an expansion of an embodiment similar to that in FIG. 14D including two n-contact points 1200, 1202 as well as the light extraction feature 1204. The current 1206 in the n-type layer 1208 has to flow laterally until it reaches an n-contact 1200, 1202. The light extraction feature 1204 is placed about half-way between the contacts 1200, 1202, where it does not interfere with any lateral current flow. FIG. 15 also depicts a dielectric mirror layer 1210, which is connected to the n-type contacts 1200, 1202 by a conductive adhesive layer 1211, and a substrate structure 1212, which can comprise a metal bond layer 1214 and a silicon layer 1216.

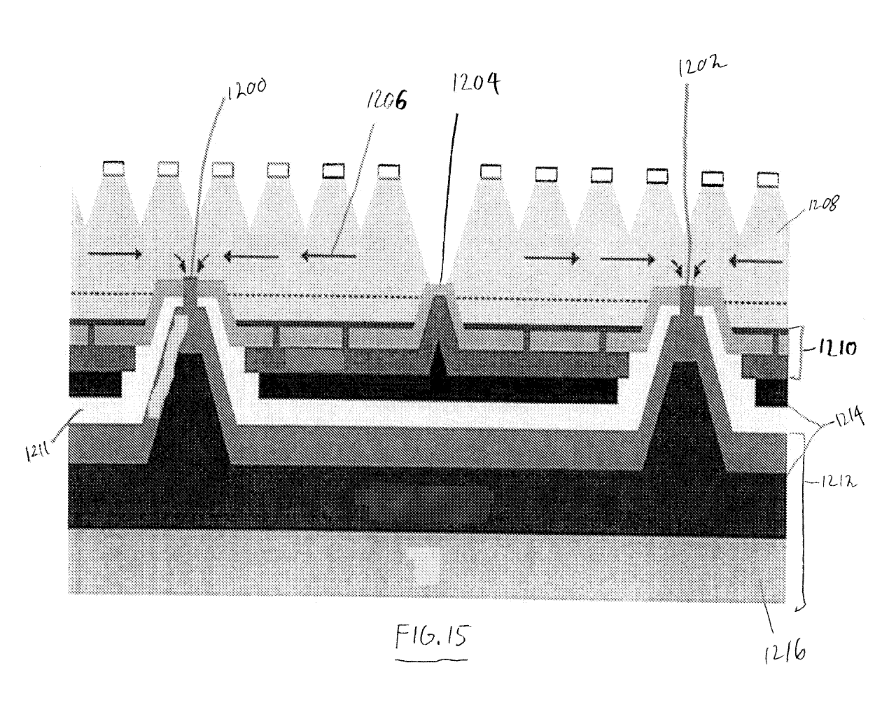

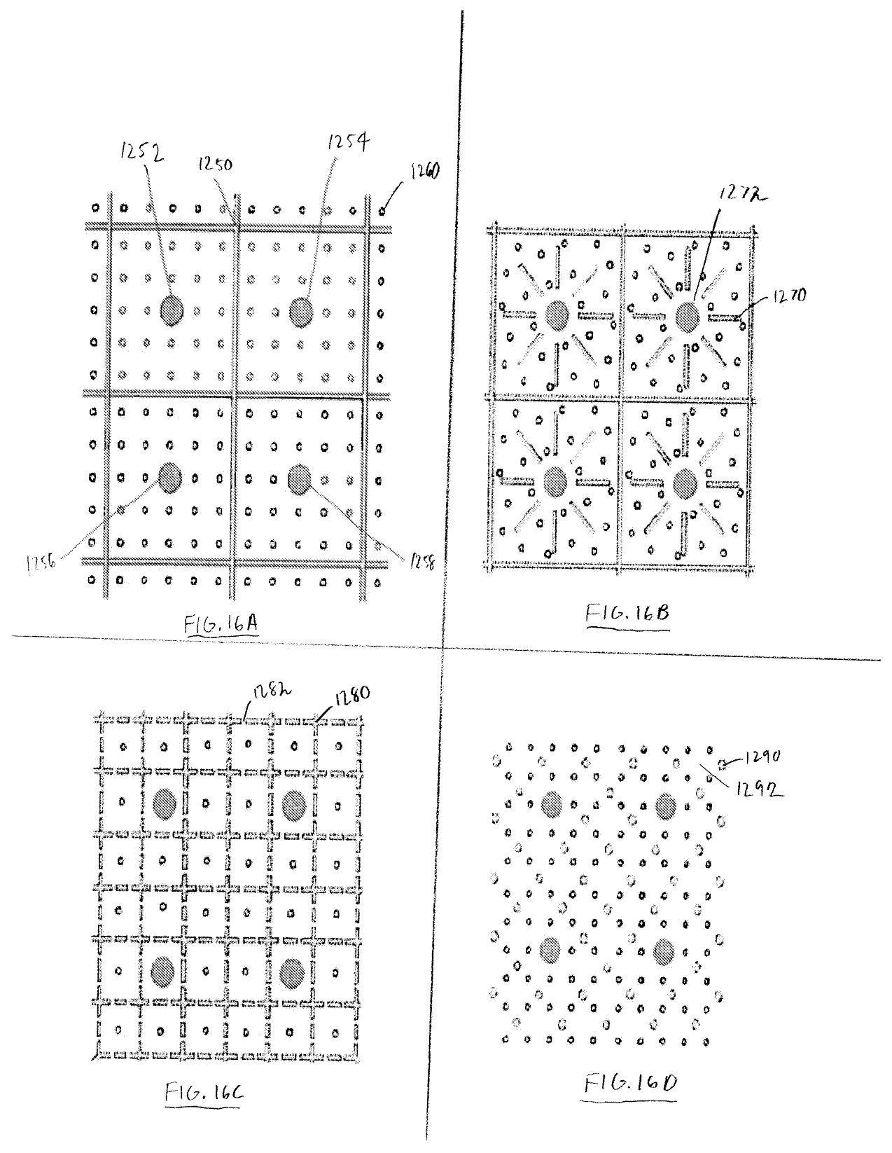

A top view of a similar contact configuration to that shown in FIG. 15 is shown in FIG. 16A, which shows a light extraction feature 1250, n-contacts 1252, 1254, 1256, 1258 and holes 1260 through the dielectric layer. As shown in FIG. 16B, in cases where extraction features 1270 are desired more frequently than the aforementioned layout allows, the light extraction features 1270 can be added running radially from each re-contact point 1272. As shown in FIG. 16C, the extraction features 1280 can also be interrupted periodically at interrupt points 1282 in order to let current through.

Furthermore, the extraction features 1290 do not have to be linear as is shown in in FIG. 16A through 16D, but can be circular with space 1292 in-between for lateral current flow. In the case where the extraction feature is a combined feature (from top and bottom), the two sides can have different lateral layouts, such that they do not overlap in all locations. This can prevent interference with lateral current flow, since in areas where top and bottom features don't overlap current can flow laterally in the remaining portion of the semiconductor.

The embodiments shown above in FIGS. 14B and 14C require further explanation regarding lateral current flow. The deep trench features from the light emission side can potentially prevent lateral current flow. When implementing these embodiments, it is therefore important that the lateral layout can allow for lateral current flow. This means that the LED cross-section perpendicular to what is shown in FIGS. 14B and 14C should not have the same deep features, and that the n-contacts have to be positioned such that current does not need to flow laterally in the cross-sections shown in the figures.

An example configuration of this is shown in FIG. 17, wherein one or more long linear n-contacts 1300 (one shown) are utilized in contrast to the circular contacts shown in FIGS. 16A through 16D above. In the embodiment shown in FIG. 17, the spacing between etch mask circles 1302 is close going from left to right (see the close-spaced groups 1304), which means the etched features are not particularly deep, and current can flow laterally in this direction. The spacing from top to bottom is wider (see the widely-spaced groups 1306), creating deeper etched features, and current flow is limited in this direction. The layout of the n-contact 1300 running top to bottom along the length of the device ensures that current can spread to all parts of the LED flowing left and right, and does not need to flow top to bottom in the semiconductor. The holes 1308 through the dielectric are also depicted in relation to the reflector-side light extraction features 1310.

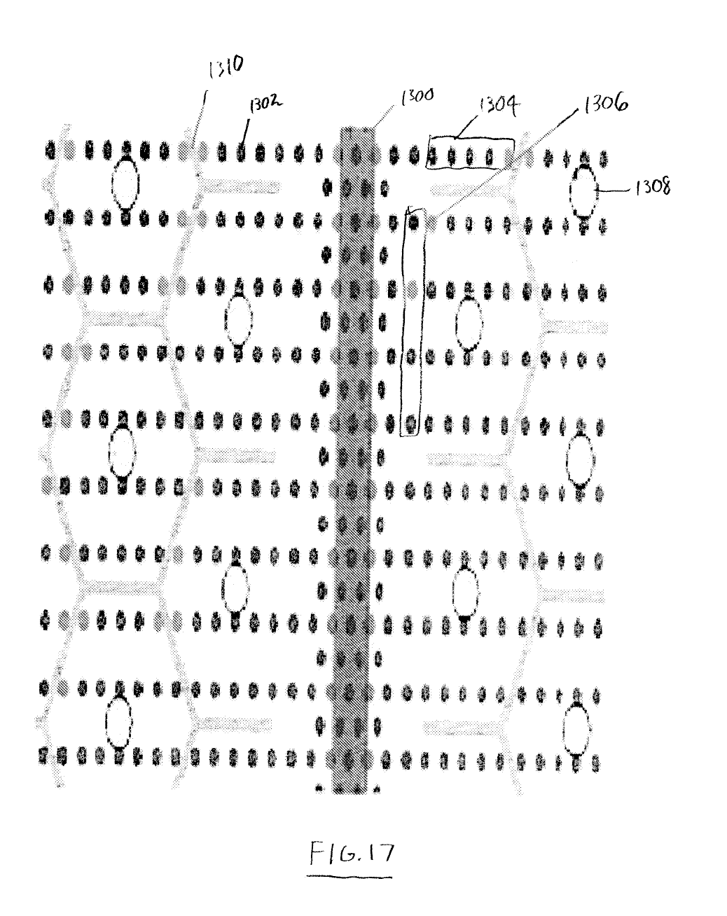

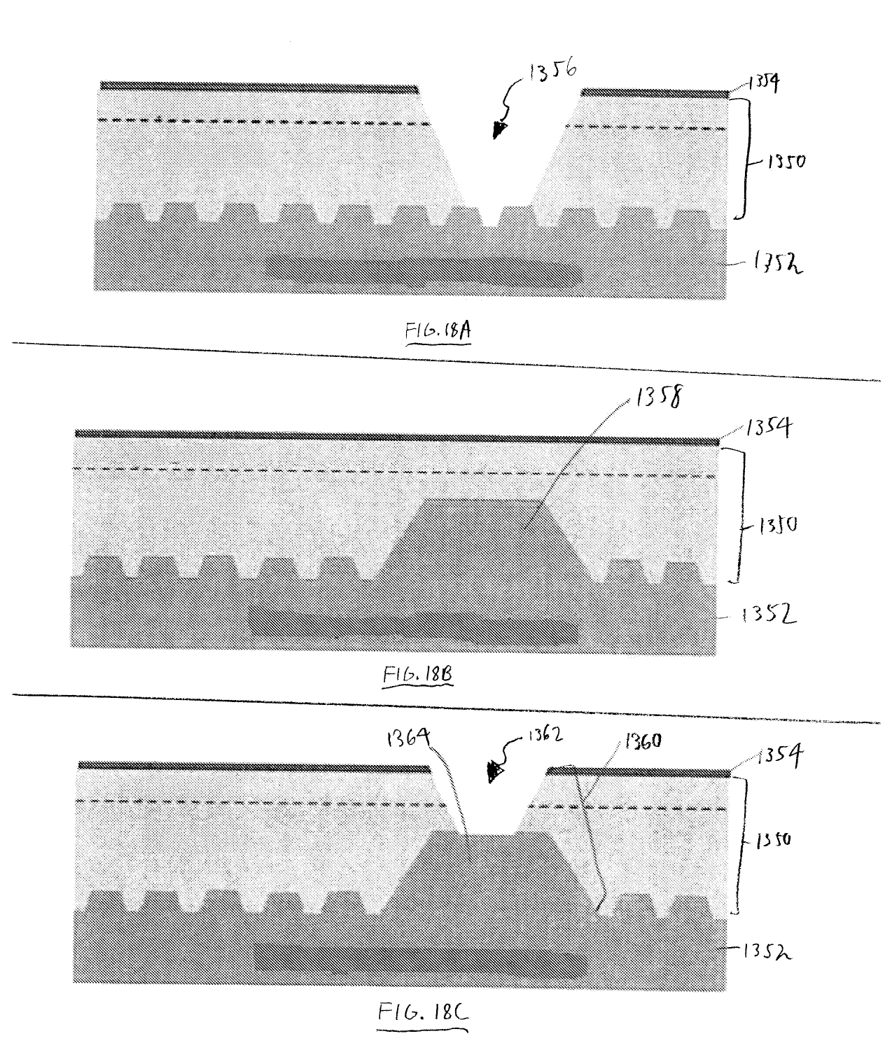

Light extraction features incorporating elements from the present invention can also be used in LED chips utilizing a transparent substrate. FIGS. 18A-18C depict embodiments where the original growth substrate is transparent (typically sapphire) and remains in the final LED (substrate has not been removed). FIGS. 18A-18C depict LED chips comprising a diode region 1350 between a transparent substrate 1352 and a TOO layer 1354. The LED chip of FIG. 18A also further comprises an indentation light extraction element 1356. The LED chip of FIG. 18B further comprises a protrusion light extraction element 1358.

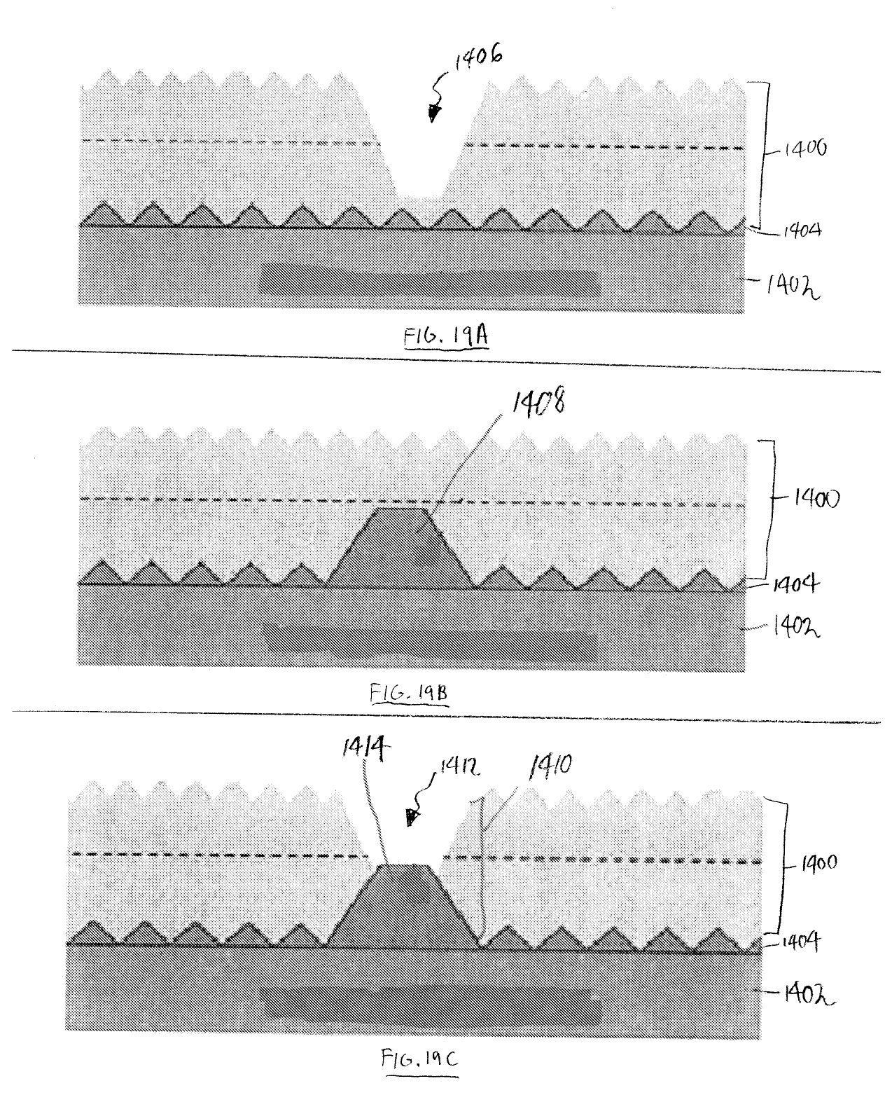

The LED chip of FIG. 18C further comprises a combined light extraction element 1360, comprising an indentation portion 1362 and a protrusion portion 1364. FIGS. 19A-19C depict LED chips where the original growth substrate has been removed, and the LED epitaxial layers have been bonded to a transparent substrate. For example red emitting AlInGaP-based LEDs. The chips comprise a diode region 1400 on a transparent substrate 1402 which is connected to the diode region 1400 via a dielectric bond 1404. The LED chip of FIG. 19A also further comprises an indentation light extraction element 1406. The LED chip of FIG. 19B further comprises a protrusion light extraction element 1408. The LED chip of FIG. 18C further comprises a combined light extraction element 1410, comprising an indentation portion 1412 and a protrusion portion 1414.

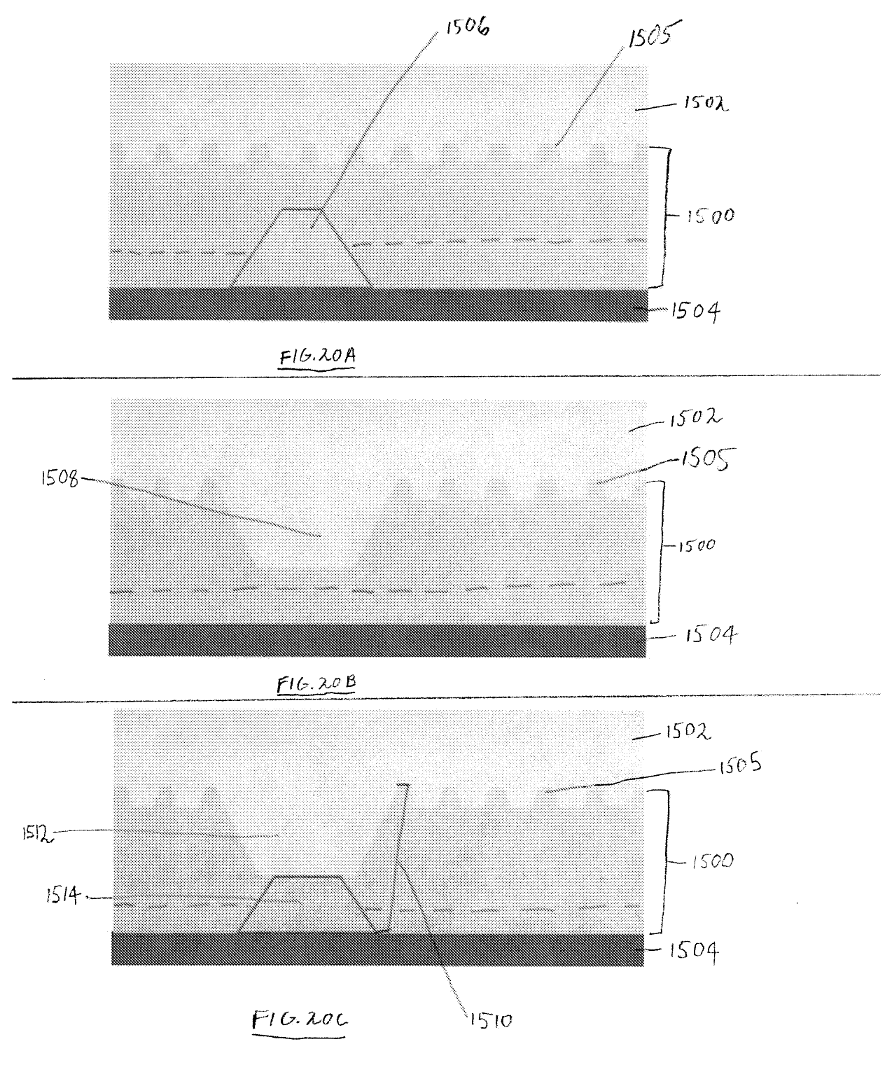

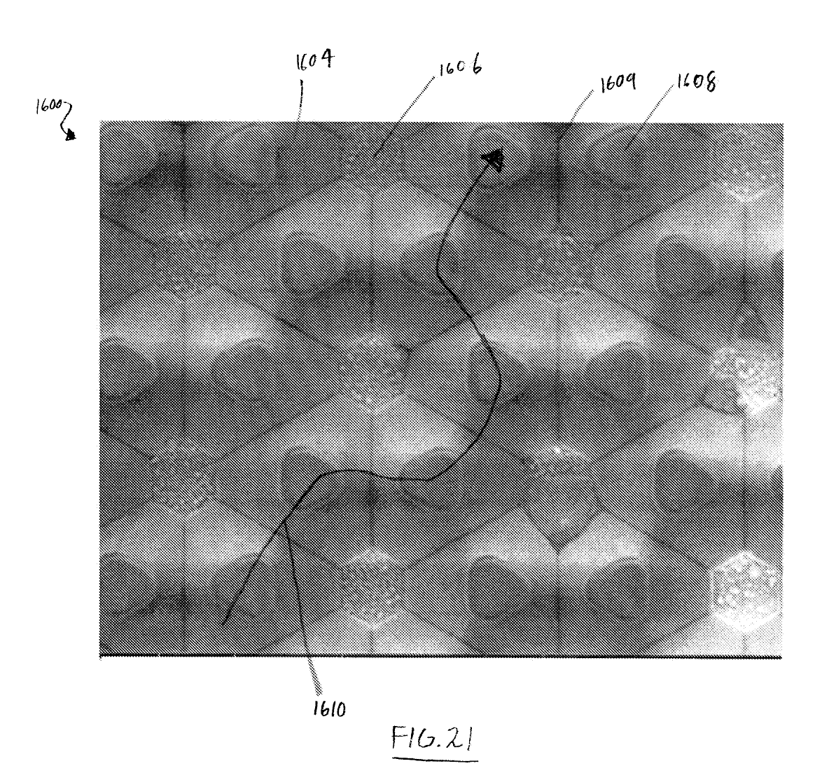

FIGS. 20A-20C show further additional embodiments, which are in a flip-chip orientation. FIGS. 20A-20C comprise a diode region 1500, a substrate 1502 and a reflector 1504. In some embodiments, the LED chips can further comprise roughened substrate interface portions 1505, such as those previously described herein. The substrate 1502 can be made of any suitable substrate material that is transparent or partially transparent to light emitted from the active region, for example, sapphire, silicon carbide, gallium arsenide and gallium nitride. As well be discussed in more detail further below, the substrate can be a growth substrate or a carrier substrate.

In some embodiments, the substrate 1502 is transparent or partially transparent and on a surface of the diode region 1500, forming an emission surface (a top emission surface in the embodiment shown). It is understood that in some embodiments there can be intervening layers between the substrate and the diode region. The reflector 1504 can be positioned on a surface of the diode region 1500 opposite the substrate 1502. When further mounted in an LED package, the reflector 1504 side of the chip can face the package substrate and the substrate can form an emission surface opposite the package substrate in a flip-chip mounting configuration.

FIG. 20A shows the LED chip further comprising a protrusion light extraction element 1506. In some embodiments, this protrusion light extraction element 1506 is formed by first forming an indentation into the diode region 1500 after it is grown on the substrate 1502 (in embodiments where the substrate 1502 is a growth substrate) and then filling the indention with a dielectric material. In some embodiments, wherein the substrate 1502 is a carrier substrate to which the diode region is later bonded and its original growth substrate removed, the protrusion light extraction element 1506 can be positioned on the original growth substrate and the diode region grown thereon.

FIG. 20B further comprises an indentation light extraction element 1508. In the embodiment shown in FIG. 20B, the indentation light extraction element 1508 is occupied by a portion of the substrate 1502. Like previously described herein in relation to FIG. 20A, this indentation feature can be formed by growing the diode region on a transparent growth substrate or can be formed separately and bonded to a carrier substrate. In FIG. 20C, the LED chip of further comprises a combined light extraction element 1510, comprising an indentation portion 1512 and a protrusion portion 1514.

FIG. 21 shows another example lateral LED chip layout 1600, such as those shown and described with regard to FIGS. 15-17 above, with the LED chip layout 1600 also being configured to address the issue of deep trench features potentially affecting current spreading. FIG. 21 shows the LED chip layout 1600 comprising diode region 1604, holes through the diode region 1606 (i.e. deep trench light extraction features), etch mask portions 1608 and light extraction features 1609. FIG. 21 also shows an example current flow path 1610 wherein current can flow around the holes 1606 in the semiconductor material between the trenches.

As shown in FIG. 21, the holes 1606 and other light extraction features 1609 can divide the diode region 1604 into multiple diode regions, which are staggered in a hexagonal arrangement. This staggered configuration allows for improved light extraction as the various diode regions 1604 interfere less with emissions from adjacent diode regions, while still allowing for adequate current flow that is not interrupted by the deep trench light extraction features 1606. The holes 1606 are circular or near circular in shape and can be arranged with the diode region in the hexagonal pattern. The holes 1606 and the light extraction features 1609 can be formed by a crystallographic self-terminated etch or any suitable method known in the art.

Although the present invention has been described in detail with reference to certain preferred configurations thereof, other versions are possible. Embodiments of the present invention can comprise any combination of compatible features shown in the various figures, and these embodiments should not be limited to those expressly illustrated and discussed. Therefore, the spirit and scope of the invention should not be limited to the versions described above.

The foregoing is intended to cover all modifications and alternative constructions falling within the spirit and scope of the invention as expressed in the appended claims, wherein no portion of the disclosure is intended, expressly or implicitly, to be dedicated to the public domain if not set forth in the claims.

We claim:

1. A light emitting diode (LED) chip, comprising:
a semiconductor material based diode region comprising an active region; and
one or more light extraction features within said diode region, said one or more light extraction features dissecting 40% or greater of the thickness of said diode region and configured to redirect light emitted from said active region to improve light extraction from an emission surface of said LED chip.

2. The LED chip of claim 1, wherein said one or more light extraction features comprise an index of refraction lower than the index of refraction of said semiconductor material.

3. The LED chip of claim 1, wherein at least one of said one or more light extraction features comprises one or more angled sidewalls.

4. The LED chip of claim 3, wherein at least one of said one or more light extraction features comprises a sidewall sloped at an angle between 20-70 degrees.

5. The LED chip of claim 4, wherein at least one of said one or more light extraction features comprises a sidewall sloped at an angle of 45 degrees.

6. The LED chip of claim 1, wherein said one or more light extraction features comprise at least two light extraction features comprising different shapes.

7. The LED chip of claim 1, wherein said one or more light extraction features comprise at least one light extraction feature opposite said emission surface.

8. The LED chip of claim 1, wherein said one or more light extraction features comprise at least one light extraction feature on the same side of said LED chip as said emission surface.

9. The LED chip of claim 1, wherein said one or more light extraction features comprise at least one protrusion.

10. The LED chip of claim 1, wherein said one or more light extraction features comprise at least one indentation.

11. The LED chip of claim 1, wherein said one or more light extraction features comprise at least one light extraction feature comprising a protrusion and an indentation.

12. The LED chip of claim 1, wherein at least one of said one or more light extraction features dissects said active region.

13. The LED chip of claim 1, wherein at least one of said at least one light extraction features comprises a reflector.

14. The LED chip of claim 13, wherein at least one of said at least one light extraction features comprises a dielectric mirror.

15. The LED chip of claim 1, wherein at least one of said at least one light extraction features comprises a size less than or equal to approximately 2 times the wavelength of light emitted from said active region.

16. The LED chip of claim 1, wherein said one of more light extraction features are configured to direct light trapped within said diode region toward said emission surface.

17. The LED chip of claim 1, wherein said one or more light extraction features are configured to redirect rays of guided light produced by total internal reflection.

18. An LED chip, comprising:
a semiconductor material based diode region comprising an active region and an emission surface;
a reflector opposite said emission surface; and
one or more light extraction features within said diode region between said reflector and said emission surface, said one or more light extraction features comprising a dielectric material protrusion opposite said emission surface.

19. The LED chip of claim 18, wherein at least one of said one or more light extraction features further comprises an indention light extraction feature on the same side of said diode region as said emission surface.

20. The LED chip of claim 18, wherein said emission surface comprises a transparent substrate on said semiconductor material.

21. An LED chip, comprising:
a semiconductor material based diode region comprising an active region and an emission surface;
a reflector opposite said emission surface; and
one or more light extraction features within said diode region between said reflector and said emission surface, said one or more light extraction features comprising an indentation on the same side of said diode region as said emission surface.

22. The LED chip of claim 21, wherein at least one of said one or more light extraction features further comprises a dielectric material protrusion opposite said emission surface.

23. The LED chip of claim 21, wherein said emission surface comprises a transparent substrate on said semiconductor material.

24. An LED chip, comprising:
a semiconductor material based diode region comprising an active region, an n-type layer and a p-type layer;
at least one anode contact contacting said p-type layer;
at least one cathode contact contacting said n-type layer; and
a plurality of light extraction features within said diode region, said plurality of light extraction features configured to redirect incoming light emitted from said active region to improve light extraction from one or more emission surfaces of said LED chip.

23. The LED chip of claim 22, wherein said plurality of light extraction features runs radially through said diode region from said at least one cathode contact.

25. The LED chip of claim 24, wherein said light extraction features in said plurality of light extraction features are spaced apart to enhance the flow of current through said diode region.

26. The LED chip of claim 24, wherein said plurality of light extraction features is configured such that said diode region is divided into multiple diode regions.

27. The LED chip of claim 26, wherein said multiple diode regions are staggered in a hexagonal configuration.

28. The LED chip of claim 24, wherein said plurality of light extraction features comprises light extraction features comprising a protrusion and an indentation.

29. The LED chip of claim 28, wherein said protrusion and said indentation do not overlap.

30. A method of improving light extraction in an LED chip, comprising:
forming a mask layer on an n-type GaN layer of a semiconductor based diode region, said diode region comprising a layer of n-type GaN on a layer of p-type GaN; and
etching said n-type GaN layer to form one or more indentation light extraction features comprising sloped sidewalls.

31. The method of claim 30, wherein forming the mask layer comprises forming multiple masked areas wherein the exposed portions of said n-type GaN layer between said multiple masked areas are configured to control etch depth during the etching process.

32. The method of claim 30, wherein at least one dielectric protrusion light extraction feature is introduced into said p-type layer prior to forming said mask layer.

33. The method of claim 32, wherein at least a portion of said mask layer is aligned with at least one of said at least one dielectric protrusion light extraction feature.

34. The method of claim 30, wherein at least one dielectric protrusion light extraction feature is introduced into said p-type layer prior to forming said mask layer such that said at least one extraction feature is aligned with at least a portion of said mask layer.
